(19) United States
(12) Patent Application Publication
(10) Pub. No.: US 2026/0078300 A1
(43) Pub. Date: Mar. 19, 2026

(54) INORGANIC-BLENDED P-TYPE SEMICONDUCTOR AND METHOD OF PREPARATION THEREOF

(71) Applicant: City University of Hong Kong, Hong Kong (CN)

(72) Inventors: Chung Yin Johnny HO, Hong Kong (CN); You MENG, Hong Kong (CN); Yuxuan ZHANG, Hong Kong (CN)

(21) Appl. No.: 18/884,267

(22) Filed: Sep. 13, 2024

(51) Int. Cl. C09K 11/88; C01B 19/00; H01L 21/02

(52) U.S. Cl. CPC C09K 11/881; C01B 19/004; C01P 2002/50; C01P 2002/72; C01P 2002/82; C01P 2002/84; C01P 2002/85; C01P 2004/03; C01P 2004/04; C01P 2006/40; C01P 2006/60; H10P 14/22; H10P 14/3434

(57) ABSTRACT

Inorganic semiconductors typically have limited p-type behavior due to the scarcity of holes and the localized valence band maximum, hindering the progress of complementary devices and circuits. In this work, we propose an inorganic blending strategy to activate the hole-transporting character in an inorganic semiconductor compound, namely tellurium-selenium-oxygen (TeSeO). By rationally combining intrinsic p-type semimetal, semiconductor, and wide-bandgap semiconductor into a single compound, the TeSeO system displays tunable bandgaps ranging from 0.7 to 2.2 eV. Wafer-scale ultrathin TeSeO films, which can be deposited at room temperature, display high hole field-effect mobility of 48.5 cm²/(Vs) and robust hole transport properties, facilitated by Te—Te (Se) portions and O—Te—O portions, respectively.

### STATEMENT REGARDING PRIOR DISCLOSURES BY THE INVENTORS OR JOINT INVENTORS UNDER 37 CFR 1.77(b)(6)

Part of the present invention was disclosed in a paper published in You Meng, et al., An inorganic-blended p-type semiconductor with robust electrical and mechanical properties, Nat Commun 15, 4440 (2024), available online 24 May 2024. This paper is a grace period inventor-originated disclosure disclosed within one year before the filing date of this application and falls within the exceptions defined under 35 USC § 102(b)(1). This paper is hereby incorporated by reference in its entirety.

### TECHNICAL FIELD

The present disclosure generally relates to group 16 p-type semiconductors and methods of preparation thereof.

### BACKGROUND

Semiconducting properties are present in numerous elements and compounds. Some examples of pure elements are found in group 14, such as the commercially important C, Si, and Ge, which are connected by covalent bonds. By sharing their outermost (valence) electrons to form a full electron shell, the stable balance of attractive/repulsive forces among atoms allows them to attain stable electronic configuration. Nonetheless, covalent bonding relies heavily on the directional nature of atomic orbitals, imposing substantial constraints on the design of covalent compounds. For instance, it only takes 4% lattice constant mismatch to make the Si—Ge system strained and possibly metastable. Moreover, owing to their stable crystal structures and chemically unreactive properties, producing high-quality covalent semiconducting materials invariably requires high-temperature growth (600° C. or higher) and subsequent annealing procedures. These factors limit the feasibility of tuning the bandgap and the flexible integration of covalent semiconductors.

On the other hand, with sharply different electronegativities, the electrostatic attraction between oppositely charged ions could form ionic or polar covalent bonds. Compound semiconductors made by these two types of chemical bonds, primarily comprising transition-metal cations from group 10 to 14, have been identified to possess respectable electron mobility, i.e., tens of cm²/(Vs) for amorphous/polycrystalline and hundreds of cm²/(Vs) for crystalline ones. However, despite extensive efforts over many years, the inferior hole mobility exhibited by their p-type counterparts has hindered the progress of complementary devices and circuits. The main causes for their poor p-type performance include the localized valence band maximum (VBM), strong self-compensation effect, and poor material stability. For instance, in p-type transition-metal oxides (halides) such as CuOₓ, SnO, and CuI, high concentrations of oxygen (halogen) vacancies typically function as compensating intrinsic defects that capture holes, thereby impeding their hole transport. To bypass these ingrained issues, an alternative material design strategy is expected to explore better p-type semiconductors.

There is thus a need for improved p-type semiconductors that overcome at least some of the disadvantages described above.

### SUMMARY

The present disclosure provides a high-mobility and air-stable p-type semiconducting system, namely tellurium-selenium-oxygen (TeSeO), which was explored based on an inorganic blending strategy (FIG. 1a). Group 16 elements, i.e., Te, Se, and O, are utilized because of their similar s²p⁴ electronic configurations and atomic radii, which endows good miscibility to form the TeSeO system. Due to the different ionization energy and electronegativity, the metallic characters of elements become more pronounced as one moves down group 16, which spans from insulator to semiconductor to metalloid. This variation allows for continuous tuning of the physical properties of the TeSeO system through different compositions. In particular, semimetal Te has high intrinsic hole mobility (˜10⁵ cm²/Vs) and small effective hole mass (˜0.3 m₀), which is covalently bonded as Te—Te or Te—Se that mainly contributes to the good hole-transport property. Semiconducting Se is used to effectively modify the bandgap (from 0.7 to 2.2 eV), oxidative ability, and crystallinity of TeSeO to meet technical requirements. Notably, the employment of O forms O—Te—O (polar covalent bonds) with a wider bandgap, endowing superior operating durability to TeSeO that is unachievable by other p-type thin-film semiconductors.

In a first aspect, provided herein is a semiconductor composition comprising tellurium, selenium, and oxygen, wherein the semiconductor composition is substantially free of Se⁴⁺.

In certain embodiments, the semiconductor composition comprises Te⁰, Se⁰, and Te⁴⁺, wherein regions comprising Te⁰ and Se⁰ are substantially crystalline or polycrystalline and regions comprising Te⁴⁺ are substantially amorphous.

In certain embodiments, the semiconductor composition has a hole mobility between 23.1-65.6 cm²/(Vs) at room temperature.

In certain embodiments, the semiconductor composition has a bandgap of 0.7 eV to 2.2 eV.

In certain embodiments, the semiconductor composition is Te₍₁₋ₓ₎SeₓO_{y}, wherein 0.1≤x≤0.9 and 0.04≤y≤0.98.

In certain embodiments, the semiconductor composition is Te₍₁₋ₓ₎SeₓO_{y}, wherein 0.1≤x≤0.3 and 0.59≤y≤0.98.

In certain embodiments, the semiconductor composition is Te₍₁₋ₓ₎SeₓO_{y}, wherein 0.1≤x≤0.3 and y±0.01=1.18-1.95x.

In certain embodiments, the semiconductor composition is Te₍₁₋ₓ₎SeₓO_{y}, wherein 0.1≤x≤0.9 and 0.04≤y≤0.98; and the semiconductor composition has a bandgap of 0.7 eV to 2.2 eV.

In certain embodiments, the semiconductor composition has a hole mobility between 23.1-65.6 cm²/(Vs).

In certain embodiments, the semiconductor composition is Te₍₁₋ₓ₎SeₓO_{y}, wherein 0.1≤x≤0.3 and 0.59≤y≤0.98; and the semiconductor composition has a bandgap of 0.7 eV to 2.2 eV.

In certain embodiments, the semiconductor composition has a hole mobility between 23.1-65.6 cm²/(Vs).

In certain embodiments, the semiconductor composition is selected from the group consisting of Te_{0.7}Se_{0.3}O_{0.59}, Te_{0.8}Se_{0.2}O_{0.80}, and Te_{0.9}Se_{0.1}O_{0.98}.

In a second aspect, provided herein is a method for preparing the semiconductor composition described herein, the method comprising:

combining tellurium (Te) powder and selenium (Se) powder thereby forming a Te—Se mixture;

depositing the Te—Se mixture on a surface of a substrate by physical vapor deposition thereby forming a Te—Se film; and

contacting the Te—Se film with oxygen plasma thereby forming the semiconductor composition.

In certain embodiments, the Te powder and the Se powder are combined in a molar ratio of 1:9 to 9:1, respectively.

In certain embodiments, the Te powder and the Se powder are combined in a molar ratio of 7:3 to 9:1, respectively.

In certain embodiments, the oxygen plasma is generated at a power of 30-100 W under a pressure of 0.1-10 Torr.

In a third aspect, provided herein is a semiconductor device comprising the semiconductor composition described herein, wherein the semiconductor device is selected from the group consisting of a thin-film transistor, a photodetector, and a solar cell.

In certain embodiments, the semiconductor device is a thin-film transistor having a hole mobility between 23.1-65.6 cm²/(Vs) or a photodetector having a response speed of about 5 μs.

### BRIEF DESCRIPTION OF THE DRAWINGS

The above and other objects and features of the present disclosure will become apparent from the following description of the disclosure, when taken in conjunction with the accompanying drawings.

FIG. 1. TeSeO synthesis and microstructure characterization. (a) Schematic of p-type TeSeO semiconducting system containing group 16 elements. (b) grazing incidence X-ray diffraction (GIXRD) patterns and (c) atomic force microscopy (AFM) images of TeSeO thin films with different compositions. Insets of (b) display the corresponding sample photographs. Inset of (c) shows the corresponding roughness values of TeSeO thin films based on root-mean-square deviation (R_{q}) and arithmetic-mean deviation (Rₐ). (d) Cross-sectional high-resolution transmission electron microscopy (HRTEM) image of Te_{0.7}Se_{0.3}O_{0.59} thin film. (e) Selected area electron diffraction (SAED) patterns of TeO_{1.16}, Te_{0.7}Se_{0.3}O_{0.59}, and Te_{0.5}Se_{0.5}O_{0.32} thin films.

FIG. 2. Chemical bonding and band structure of TeSeO. X-ray photoelectron spectroscopy (XPS) (a) Te 3d, (b) O 1s, and (c) Se 3d analysis of TeSeO thin films with different compositions. (d) Absorption spectra of the prepared films with different compositions. Ultraviolet photoelectron spectroscopy (UPS) spectra of TeSeO thin films at (e) secondary electron cut-off regions and (f) valence-band regions. (g) Energy band diagram of the TeSeO thin films with changing compositions.

FIG. 3. Transport properties and electrical robustness of TeSeO. Output curves of (a) Te_{0.7}Se_{0.3}O_{0.59}, (b) Te_{0.8}Se_{0.2}O_{0.8}, and (c) Te_{0.9}Se_{0.1}O_{0.98} TFTs. Inset of (a) shows the optical image of the device. Transfer curves and hole mobilities of (d) Te_{0.7}Se_{0.3}O_{0.59}, (e) Te_{0.8}Se_{0.2}O_{0.8}, and (f) Te_{0.9}Se_{0.1}O_{0.98} TFTs. (g) On/off switching measurements of Te_{0.8}Se_{0.2}Oₓ and Te_{0.8}Se_{0.2} TFTs and representative on/off switching cycles.

FIG. 4. Nanopatterned TeSeO and broadband photodetection. (a) SEM images of the nanosphere lithography process consisting of nanosphere assembly, size reduction, TeSeO deposition, and nanosphere lift-off. (b-f) Broadband UV-vis-SWIR operation of flexible nanopatterned TeSeO photodetectors with a chopped frequency of 0.2 Hz. (g) Optical responsivity of TeSeO with different compositions under various incident light wavelengths.

FIG. 5. Mechanical analysis of honeycomb TeSeO optoelectronics. (a) finite element analysis (FEA) simulation of the TeSeO layer/PI substrate model at a bending radius of 1.5 mm. (b) Top views of strain distribution on the bent TeSeO honeycomb layer and (c) representative area. (d) The device photocurrent under on/off switching light illumination (0.2 Hz) as a function of bending cycles. (e) Time-resolved photoresponse of Te_{0.7}Se_{0.3}O_{0.59} PDs measured at 1550 nm illumination with a chopped frequency of 10 kHz. Comparison of (f) photoresponse speed and (g) hole mobility of metal oxides, metal halides, perovskite halides, organic materials, TeSeO, etc.

FIG. 6. GIXRD patterns of TeSeO thin films with different compositions and XRD pattern of the α-TeO₂ powder. All the diffraction peaks agree with the typical hexagonal crystal system with P3₁21 [152] space group composed of chalcogen chains along the c axis. The diffraction peak positions shift slightly to higher angles with increasing Se content, indicating the decrease of the lattice constant. This finding could result from the Se substitution in Te sites, in which the Se atom has a relatively smaller radius of 0.14 nm than that of the Te atom (0.16 nm). At the same time, the increased full width at half-maximum of the diffraction peaks also reveals the suppressed material crystallinity.

FIG. 7. (a) Raman studies of TeSeO thin films with different compositions, where three first-order Raman active modes located at 90 cm⁻¹ (E₁ transverse (TO) phonon mode), 118 cm⁻¹ (A₁ mode), and 138 cm⁻¹ (E₂ mode) were identified. (b) Schematic vibration patterns of the Raman modes of E₁, A₁, and E₂ in chiral-chain Te or Se materials. The E₁ and E₂ modes represent bond-bending and bond-stretching with a larger admixture, respectively, whereas the A₁ mode is caused by chain expansion in the basal plane.

FIG. 8. (a) Cross-sectional high-angle annular dark-field scanning transmission electron microscopy (STEM-HAADF) image and (b) energy-dispersive X-ray spectroscopy (EDS) mapping of the TeSeO film. The distributions of Te, Se, and O signals are relatively uniform without noticeable element segregation.

FIG. 9. XPS (a) Te 3d, (b) O 1s, and (c) Se 3d analysis of ten different positions of TeSeO thin films grown on a 4-inch SiO₂/Si wafer.

FIG. 10. XPS Te 3d analysis of (a) TeO_{1.16}, (b) Te_{0.7}Se_{0.3}O_{0.59}, (c) Te_{0.5}Se_{0.5}O_{0.32}, and (d) Te_{0.3}Se_{0.7}O_{0.15} thin films. (e) XPS Te 3d_{5/2} peak analysis of TeSeO thin films with different compositions. (f) Extracted Te⁴⁺/(Te⁰+Te⁴⁺) ratios of TeSeO thin films. The coexisted Te⁴⁺ and Te⁰ peaks are clearly distinguished at ˜572.8 eV and ˜576.0 eV, respectively, which means the partial oxidation of Te. With increasing Se content, the corresponding Te⁴⁺/(Te⁰+Te⁴⁺) ratios decrease from ˜58% (TeO_{1.16}) to ˜25% (Te_{0.3}Se_{0.7}O_{0.59}), revealing that the Se content can suppress the binding process between Te and O.

FIG. 11. XPS (a) Se 3d and (b) O 1s peak analysis of TeSeO thin films with different compositions. The distinct peaks observed around 530.2 eV in the O 1s spectra imply the O acts as lattice oxygen species O—Te—O. Generally, the adsorbed oxygen or hydroxyl group has higher binding energy, around 532 eV, which is not witnessed in our TeSeO films. At the same time, no Se⁴⁺ (typically around 60 eV) peak is found from Se 3d spectra, mainly owing to its larger electronegativity (2.55) than that of Te (2.1), which makes it difficult to react with oxygen molecules to form SeO₂.

FIG. 12. Transfer characteristics of wafer-scale Te_{0.8}Se_{0.2}O_{0.8} TFT array (10×10 array) using (a) linear y-coordinate and (b) logarithm y-coordinate. The corresponding performance distribution of (c) mobility and (d) V_{TH} for wafer-scale Te_{0.8}Se_{0.2}O_{0.8} TFT array. The TFT array shows 100% device yield with hole mobility of 48.2±8.4 cm²/(Vs), Iₒₙ/I_{off} of 10⁴˜10⁵, and V_{TH} of −4.2±1.3 V.

FIG. 13. (a) Negative-bias stress (NBS) test of Te_{0.8}Se_{0.2}O_{0.8} TFT. Extracted (b) threshold voltages and (c) on currents of Te_{0.8}Se_{0.2}O_{0.8} TFT in NBS study. After being gated at −20 V for 2 hours, the corresponding V_{TH} shifted negatively from −5 to −8.8 V without noticeable subthreshold swing variation under NBS.

FIG. 14. (a) Transfer curve and (b) output curve of Te_{0.8}Se_{0.2}O_{0.8} TFT measured after fabrication. (c) Transfer curve and (d) output curve of Te_{0.8}Se_{0.2}O_{0.8} TFT measured after 300-day storage in ambient. After 300 days of ambient storage, the FET performances are not significantly degraded even without device encapsulation, benefiting from the partial oxidation in TeSeO thin films.

FIG. 15. (a) SEM images of the nanosphere lithography process that consists of (a) nanosphere assembling, (b) size reduction, (c) TeSeO deposition, and nanosphere lift-off.

FIG. 16. (a) FEA simulation of the TeSeO layer/PI substrate model at a bending radius of 1.5 mm. (b) Top view of strain distribution on the bent TeSeO flat film. (c) Top view of strain distribution on the bent TeSeO honeycomb layer.

FIG. 17. The Te_{0.7}Se_{0.3}O_{0.59} thin film (without nanopatterned) device photocurrent under on/off switching light illumination (0.2 Hz) measured before bending tests, after 2000, 4000, and 6000 bending cycles, respectively.

FIG. 18. Time-resolved photoresponse of Te_{0.7}Se_{0.3}O_{0.59} honeycomb layer measured at 1550 nm illumination with a chopped frequency of 10 KHz.

FIG. 19. Summary of composition ratios of TeSeO films and mole ratios between Te⁰ and Te⁴⁺.

FIG. 20. Summary of the Hall mobilities and hole concentrations of TeSeO thin films.

FIG. 21. Performance summary of TFTs based on p-type semiconducting thin films, including metal oxides, metal halides, perovskites, organic materials, CNT thin films, and TeSeO.

FIG. 22. Performance summary of PDs based on Te, perovskite halides, metal oxides, Group III-Vs, layered materials, and TeSeO.

### DETAILED DESCRIPTION

### Definitions

The following terms shall be used to describe the present invention. In the absence of a specific definition set forth herein, the terms used to describe the present invention shall be given their common meaning as understood by those of ordinary skill in the art.

Throughout the present disclosure, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the present invention.

Furthermore, throughout the present disclosure and claims, unless the context requires otherwise, the word “include” or variations such as “includes” or “including”, will be understood to imply the inclusion of a stated integer or group of integers, but not the exclusion of any other integer or group of integers.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10%, ±7%, ±5%, ±3%, ±1%, or ±0% variation from the nominal value unless otherwise indicated or inferred.

As used herein, the term “substantially free” means the indicated compound, material, component, etc., is minimally present or not present at all, e.g., at a level of about 5% by weight or less, 1% by weight or less, 4% by weight or less, 3% by weight or less, 2% by weight or less, 1% by weight or less, 0.75% by weight or less, 0.50% by weight or less, 0.25% by weight or less, 0.2% by weight or less, 0.15% by weight or less, 0.10% by weight or less, or 0.05% by weight or less, or 0.01% by weight or less, or 0.001% by weight or less, or not present, unless otherwise specified.

As used herein, the term “crystalline” indicates that the material has a regular ordered internal structure at the molecular level when in the solid phase, and the crystalline material gives a distinctive X-ray diffraction partem with defined peaks.

As used herein, the term “polycrystalline” refers to a compound, material, component, etc. comprising a plurality of crystallites (grains) that are bonded directly together by interparticle bonds. The size of the grains may be on the nanoscale, microscale, millimeter scale or vary from nanometers to millimeters, nanometers to micrometers, or micrometers to millimeters. The crystal structures of the individual grains may be randomly oriented in space within the polycrystalline material.

As used herein, the term “substantially polycrystalline” refers to a material in which greater than 70%; or greater than 75%; or greater than 80%; or greater than 85%; or greater than 90%; or greater than 95%, or greater than 99% of the material is polycrystalline. “Substantially crystalline” can also refer to material that has no more than about 10% amorphous, or no more than about 10% amorphous, or no more than about 5% amorphous, or no more than about 2% amorphous.

As used herein, the term “substantially amorphous” refers to a material in which greater than 70%; or greater than 75%; or greater than 80%; or greater than 85%; or greater than 90%; or greater than 95%, or greater than 99% of the material is amorphous. “Substantially amorphous” can also refer to a material that has no more than about 20% crystallinity, or no more than about 10% crystallinity, or no more than about 5% crystallinity, or no more than about 2% crystallinity.

Provided herein is a semiconductor composition comprising tellurium, selenium, and oxygen. The semiconductor composition can comprise Te⁰, Se⁰, and Te⁴⁺, e.g., in the form of TeO₂.

In certain embodiments, the semiconductor composition is substantially free of Se⁴⁺ (e.g., in the form of SeO₂). In certain embodiments, the semiconductor composition comprises less than 1% by weight Se⁴⁺, less than 0.75% by weight Se⁴⁺, less than 0.5% by weight Se⁴⁺, less than 0.25% by weight Se⁴⁺, less than 0.2% by weight Se⁴⁺, less than 0.1% by weight Se⁴⁺, less than 0.05% by weight Se⁴⁺, less than 0.01% by weight Se⁴⁺, or no Se⁴⁺. In certain embodiments, Se⁴⁺ cannot be detected by XPS.

Regions of the semiconductor composition comprising Te⁰ and/or Se⁰ may have a predominately crystalline structure. However, it is not a requirement that the entire semiconductor composition region comprising Te⁰ and/or Se⁰ be uniformly crystalline or polycrystalline. In certain embodiments, regions of the semiconductor composition comprising Te⁰ and/or Se⁰ may be polycrystalline where crystalline regions are interrupted by grain boundaries. The grain boundaries may have a random and/or textured orientation. The crystalline regions comprising Te⁰ and/or Se⁰ may account for greater than 90% by volume of the semiconductor composition regions comprising Te⁰ and/or Se⁰, in certain embodiments. In other embodiments, the crystalline regions comprising Te⁰ and/or Se⁰ may account for greater than 92%, 95%, 97%, 98%, 99%, or 99.9% of the volume of the regions of the semiconductor composition comprising Te⁰ and/or Se⁰. In certain embodiments, the crystalline regions comprising Te⁰ and/or Se⁰ may account for a volume of the regions of the semiconductor composition comprising Te⁰ and/or Se⁰ in the range of 70% to 100%, 80% to 100%, 90% to 100%, 95% to 100%, 96% to 100%, 97% to 100%, 98% to 100%, 99% to 100%, 99.9 to 100%, or any value or range of values within those ranges.

Regions of the semiconductor composition comprising Te⁴⁺ may have a predominately amorphous structure. The amorphous regions comprising Te⁴⁺ may account for greater than 90% by volume of the semiconductor composition regions comprising Te⁴⁺, in certain embodiments. In other embodiments, the amorphous regions comprising Te⁴⁺ may account for greater than 92%, 95%, 97%, 98%, 99%, or 99.9% of the volume of the regions of the semiconductor composition comprising Te⁴⁺. In certain embodiments, the amorphous regions comprising Te⁴⁺ may account for a volume of the regions of the semiconductor composition comprising Te⁴⁺ in the range of 70% to 100%, 80% to 100%, 90% to 100%, 95% to 100%, 96% to 100%, 97% to 100%, 98% to 100%, 99% to 100%, 99.9 to 100%, or any value or range of values within those ranges.

The semiconductor composition can comprise Se and Te in a molar ratio of 3:7 or less, 1:3 or less, 1:4 or less, 3:17 or less, 1:9 or less, 9:91 or less, 8:92 or less, 7:93 or less, 6:94 or less, 5:95 or less, 4:96 or less, 3:97 or less, 2:98 or less, 1:99 or less, respectively. In certain embodiments, the semiconductor composition comprises Se and Te in a molar ratio of 5:95 to 3:7, 1:9 to 3:7, 5:95 to 3:7, 3:17 to 3:7, 1:4 to 3:7, or 1:3 to 3:7, respectively.

In certain embodiments, the semiconductor composition can be represented by the chemical formula: Te₍₁₋ₓ₎SeₓO_{y}, wherein x is 0.1≤x≤0.9 and y is 0.04≤y≤0.98. In certain embodiments, x is 0.1≤x≤0.8 and y is 0.09≤y≤0.98, 0.1≤x≤0.7 and y is 0.15≤y≤0.98, 0.1≤x≤0.6 and y is 0.23≤y≤0.98, 0.1≤x≤0.5 and y is 0.32≤y≤0.98, 0.1≤x≤0.3 and y is 0.44≤y≤0.98, 0.1≤x≤0.3 and y is 0.59≤y≤0.98, or 0.1≤x≤0.2 and y is 0.80≤y≤0.98. In certain embodiments, the semiconductor composition is represented by the chemical formula: Te₍₁₋ₓ₎SeₓO_{y}, wherein x is 0.1≤x≤0.3 and y±0.01, 0.05, or 0 is 1.18-1.95x. In certain embodiments, the semiconductor composition is represented by the chemical formula: Te_{0.7}Se_{0.3}O_{0.59}, Te_{0.8}Se_{0.2}O_{0.80}, or Te_{0.9}Se_{0.1}O_{0.98}.

Advantageously, the hole mobility and band gap of the semiconductor composition can be modified by adjusting the chemical composition of the semiconductor composition described herein.

In certain embodiments, the semiconductor composition has a bandgap of 0.7 eV to 2.2 eV, 0.9 eV to 2.2 eV, 1.0 eV to 2.2 eV, 1.1 eV to 2.2 eV, 1.3 eV to 2.2 eV, 1.4 eV to 2.2 eV, 1.5 eV to 2.2 eV, 1.6 eV to 2.2 eV, 1.7 eV to 2.2 eV, 1.8 eV to 2.2 eV, 1.9 eV to 2.2 eV, 2.0 eV to 2.2 eV, 2.1 eV to 2.2 eV, 0.7 eV to 2.1 eV, 0.7 eV to 2.0 eV, 0.7 eV to 1.9 eV, 0.7 eV to 1.8 eV, 0.7 eV to 1.7 eV, 0.7 eV to 1.6 eV, 0.7 eV to 1.5 eV, 0.7 eV to 1.4 eV, 0.7 eV to 1.3 eV, 0.7 eV to 1.2 eV, 0.7 eV to 1.1 eV, 0.7 eV to 1.0 eV, 0.7 eV to 0.9 eV, or 0.7 eV to 0.8 eV.

In certain embodiments, the semiconductor composition has a hole mobility at room temperature between 23.1-65.6 cm²/(Vs), 48.5-65.6 cm²/(Vs), 23.1-48.5 cm²/(Vs), 25-60 cm²/(Vs), 30-55 cm²/(Vs), 35-50 cm²/(Vs), 40-45 cm²/(Vs), 25-55 cm²/(Vs), 25-50 cm²/(Vs), 25-45 cm²/(Vs), 25-40 cm²/(Vs), 25-35 cm²/(Vs), 25-30 cm²/(Vs), 30-60 cm²/(Vs), 35-60 cm²/(Vs), 40-60 cm²/(Vs), 45-60 cm²/(Vs), 50-60 cm²/(Vs), or 55-60 cm²/(Vs).

The semiconductor composition described herein can be readily prepared from readily available by persons of ordinary skill in the art using starting materials. In certain embodiments, the semiconductor composition described herein is prepared according a method comprising: combining tellurium (Te) powder and selenium (Se) powder thereby forming a Te—Se mixture; depositing the Te—Se mixture on a surface of a substrate by physical vapor deposition thereby forming a Te—Se film; and contacting the Te—Se film with oxygen plasma thereby forming the semiconductor composition.

The particle size of the Te powder and Se powder is not particularly limited. In certain embodiments, each of the Te powder and Se powder is Mesh 20, 30, 40, 50, 60, 70, 80, 90, 100, 150, 200, 250, or 300. The Te powder and Se powder can be purchased directly or can optionally be prepared from Te powder and Se powder having a larger size. There are various known methods for controlling the particle size of substances, including reduction by comminution or de-agglomeration by milling and/or sieving. Exemplary methods for particle reduction include, but are not limited to jet milling, hammer milling, compression milling and tumble milling processes (e.g., ball milling).

The Se powder and Te powder can be combined in a molar ratio of 3:7 or less, 1:3 or less, 1:4 or less, 3:17 or less, 1:9 or less, 9:91 or less, 8:92 or less, 7:93 or less, 6:94 or less, 5:95 or less, 4:96 or less, 3:97 or less, 2:98 or less, 1:99 or less, respectively. In certain embodiments, Se powder and Te powder are combined in a molar ratio between 5:95 to 3:7, 1:9 to 3:7, 5:95 to 3:7, 3:17 to 3:7, 1:4 to 3:7, or 1:3 to 3:7, respectively.

The substrate is not particularly limited, and all substrates are contemplated by the present disclosure. In certain embodiments, the substrate is a metal or metal alloy, such as gold, copper, platinum; a polymer, such as polyimide or a photoresist; a ceramic, such as alumina or zirconia; silicon, geranium, or SiO₂.

Physical vapor deposition of the Te—Se mixture on the substrate can be conducted using thermal evaporation at a chamber pressure below 4×10⁻⁶ Torr at room temperature.

The approporate oxygen plasma treatment conditions can be readily selected by a person of ordinary skill in the art based on the chemical composition of the starting material and the desired amount of oxygen implanation in the desired semicondutor composition. In certain embodiments, oxygen plasma is generated at a power of 10-100 W, 20-100 W, 30-100 W, 40-100 W, 50-100 W, 60-100 W, 70-100 W, 80-100 W, 90-100 W, 10-90 W, 10-80 W, 10-70 W, 10-60 W, 10-50 W, 10-40 W, 20-40 W, or 25-35 W under a pressure of 0.1-10 Torr, 0.1-9 Torr, 0.1-8 Torr, 0.1-7 Torr, 0.1-6 Torr, 0.1-5 Torr, 0.1-4 Torr, 0.1-3 Torr, 0.1-2 Torr, 0.1-1 Torr, 0.1-0.9 Torr, 0.1-0.8 Torr, 0.1-0.7 Torr, 0.1-0.6 Torr, 0.1-0.5 Torr, or 0.2-0.4 Torr. In certain embodiments, oxygen plasma is generated at a power of about 30 W and a pressure of about 0.26 Torr. Oxygen plasma treatment can be conducted until the desired amount of oxygen implamanetion is acehived. In certain embodiments, oxygen plasma treatment is conducted for about 60 seconds.

The present disclosure also provides a semiconductor device comprising the semiconductor material described herein. Exemplary semiconductor devices include, but are not limited, to a thin-film transistor, a photodetector, a solar cell, and other optoelectronic devices. In certain embodiments, the semiconductor device is a thin-film transistor having a hole mobility between 23.1-65.6 cm²/(Vs) or a photodetector having a response speed of about 5 μs.

### TeSeO Synthesis and Microstructure Characterization

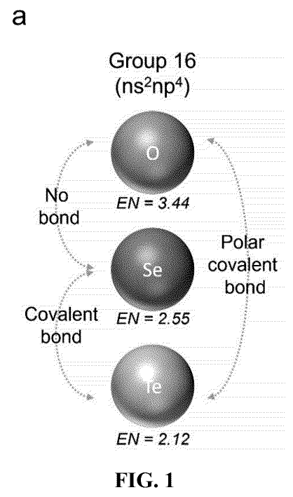

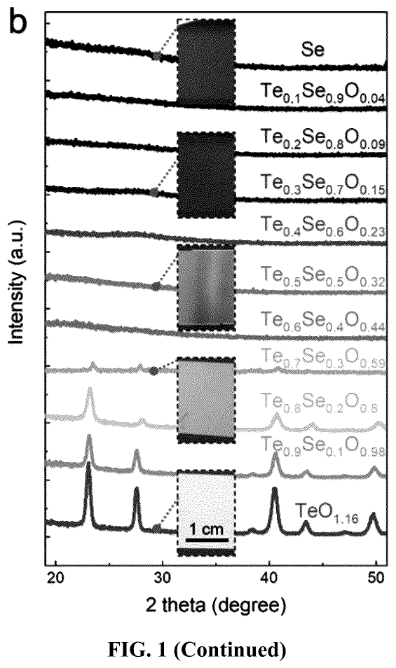

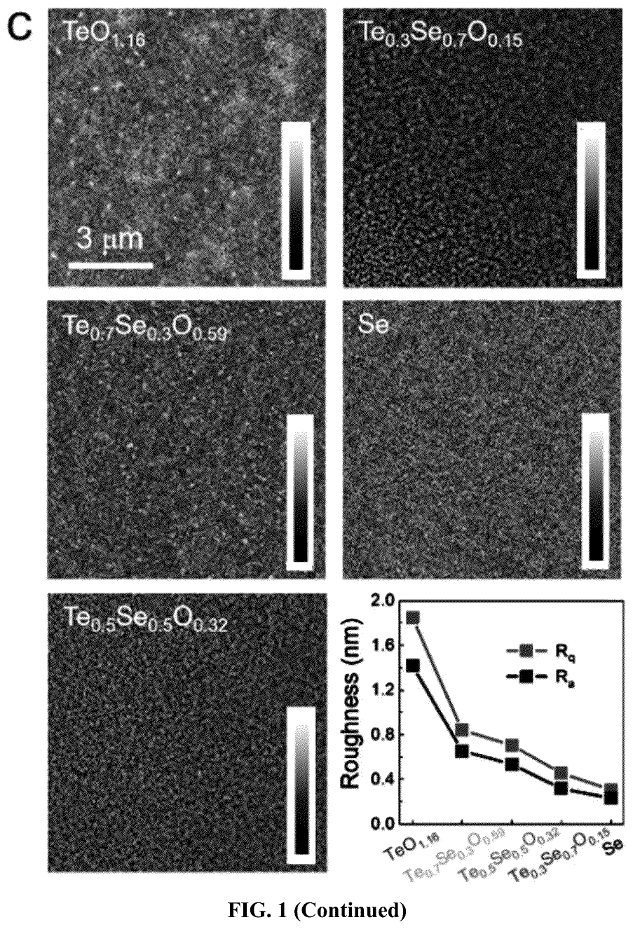

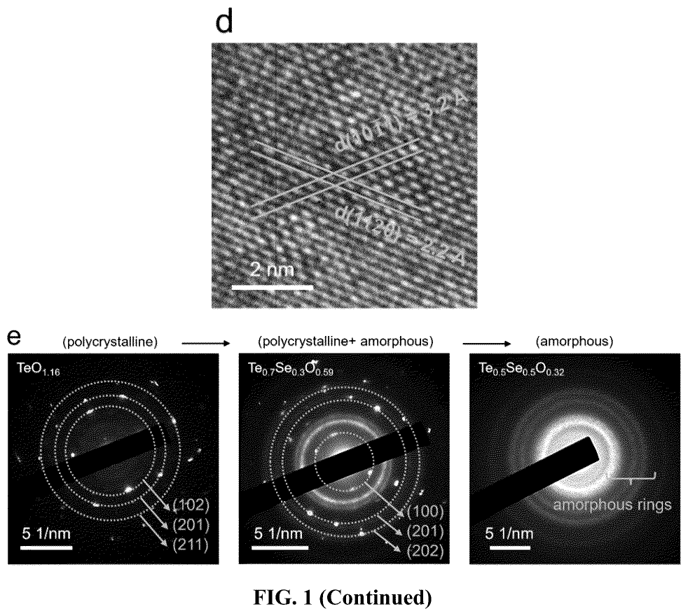

To satisfy the scalable processing, in this work, TeSeO thin films were produced by room-temperature physical vapor deposition (PVD) combined with post-oxygen implantation. The crystal structures of TeSeO thin films were characterized by a GIXRD. As shown in FIG. 1b, the TeSeO samples with relatively high Te content (Te:Se≥7:3) show a polycrystalline nature, while the Se-rich samples (Te:Se≤6:4) are found to be amorphous. The diffraction peaks located at 23.1, 27.6, 40.5, and 49.7° agree well with those of (100), (101), (110), and (201)

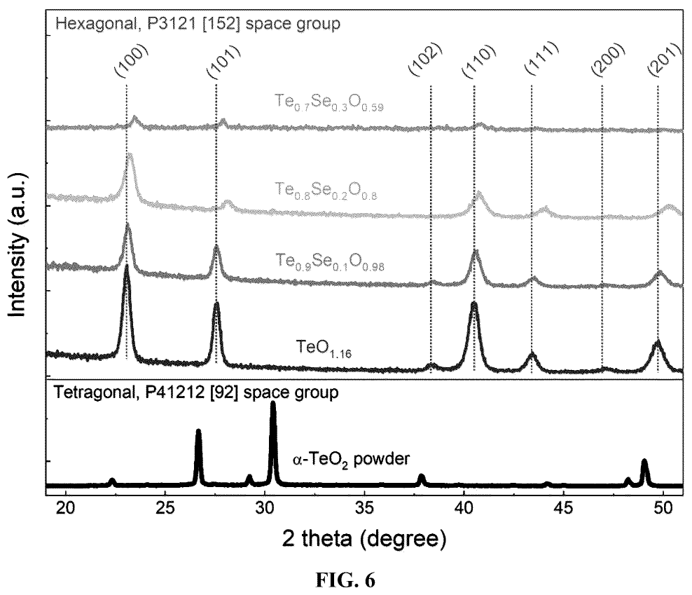

planes, respectively, of hexagonal system with P3₁21 space group that is composed of chalcogen chains along the c axis. All the diffraction peak positions slightly shift to higher angles with increasing Se content (FIG. 6), indicating the decrease of the lattice constant. At the same time, the increased full width at half-maximum of the diffraction peaks also reveals the suppressed material crystallinity. As strong glass former, the further addition of Se contents (Te:Se≤6:4) completely disturbs the crystallization process of TeSeO, leading to the polycrystalline-to-amorphous phase transition. Remarkably, with the vigorous compositional changing of TeSeO thin films, the samples undergo significant color changes from metallic luster for TeO_{1.16} to dark red for Se-rich samples, as the photographs depicted in the insets of FIG. 1b.

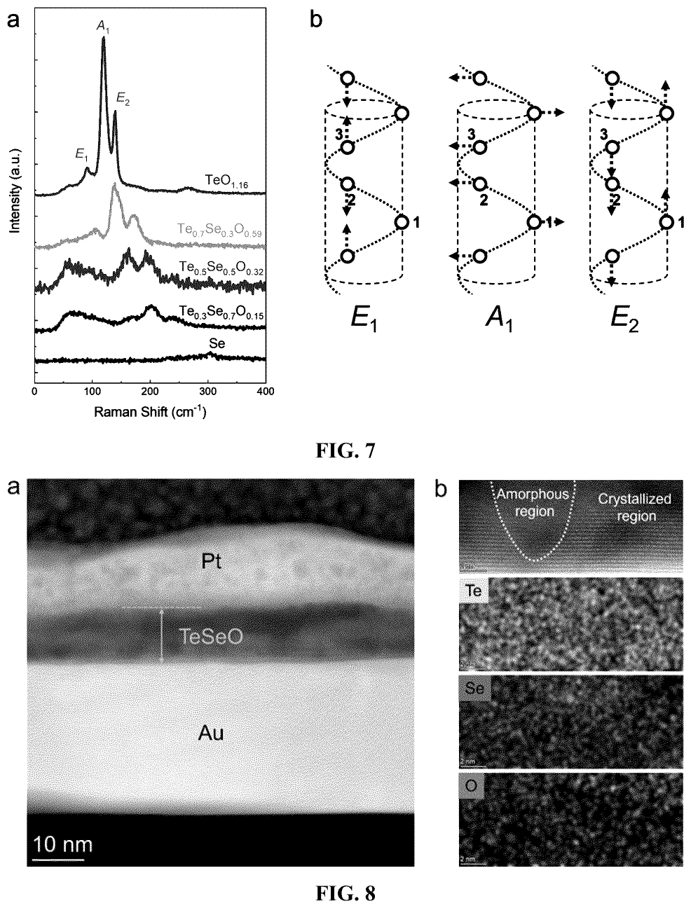

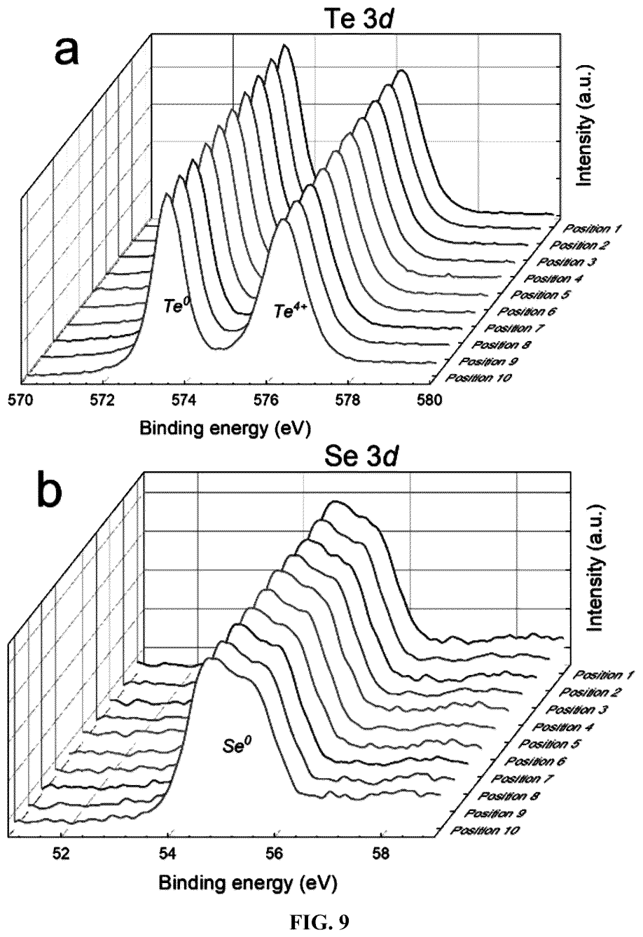

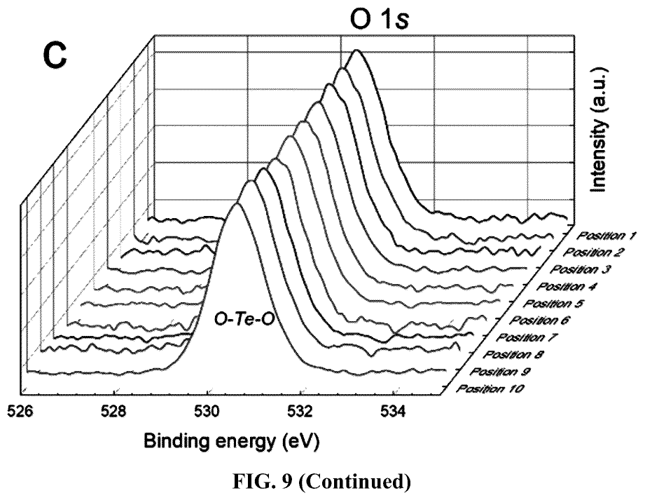

The Raman spectroscopy presented in FIG. 7 identified three first-order Raman active Te/Se helical chain modes, including E₁ transverse (TO) phonon mode, A₁ mode, and E₂ mode. Also, Se substituted for Te gives rise to an increase in the stretching frequency and the broadening of Raman bands. The undiscovered O-related Raman vibrations suggest the disordered nature of corresponding oxides that cannot efficiently enable the inelastic scattering of photons. To directly check the elemental distribution, a combination of EDS mapping and XPS were conducted on TeSeO thin films (FIGS. 8 and 9), where the uniform elemental distributions of Te, Se, and O are observed across the probed region. Moreover, the surface morphologies of TeSeO thin films with different composition ratios were examined by atomic force microscopy (AFM) with a scanning area of 10×10 μm (FIG. 1c). All the TeSeO thin films are smooth, uniform, and crack-free, which is crucial for practical devices. The extracted arithmetic mean deviation of roughness decreases from 1.8 nm to 0.3 nm with increasing Se content (inset of FIG. 1c), mainly due to the decreasing grain sizes.

The microscopic structures of the TeSeO thin films were further analyzed by cross-sectional high-resolution transmission electron microscopy (HRTEM), as depicted in FIG. 1d. The HRTEM image shows clear lattice fringes with lattice spacings of 3.2 Å and 2.2 Å for Te_{0.7}Se_{0.3}O_{0.59}, which corresponds to the (101̅1) and (112̅0) crystalline planes of hexagonal Te/Se, respectively. The corresponding selected-area electron diffraction (SAED) pattern of Te_{0.7}Se_{0.3}O_{0.59} shows a few diffraction spots (FIG. 1e), further indicating its polycrystalline structure. The observed characteristic diffuse halo, particularly evident in Te_{0.5}Se_{0.5}O_{0.32}, indicates that the addition of Se induces a polycrystalline-to-amorphous phase transition in TeSeO. Overall, no O-related phase diffraction pattern was detected in the SAED study, suggesting an amorphous state of oxides in TeSeO. The above microstructure analysis agrees well with that from XRD and Raman studies.

### Chemical Bonding and Band Structure of TeSeO

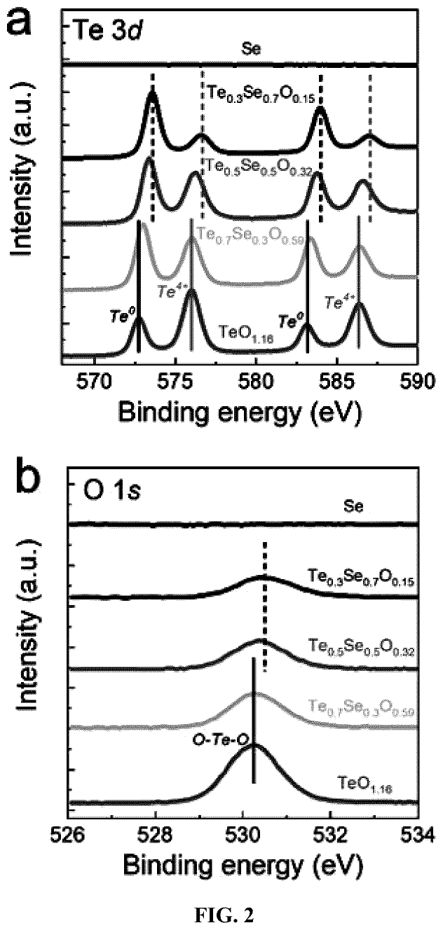

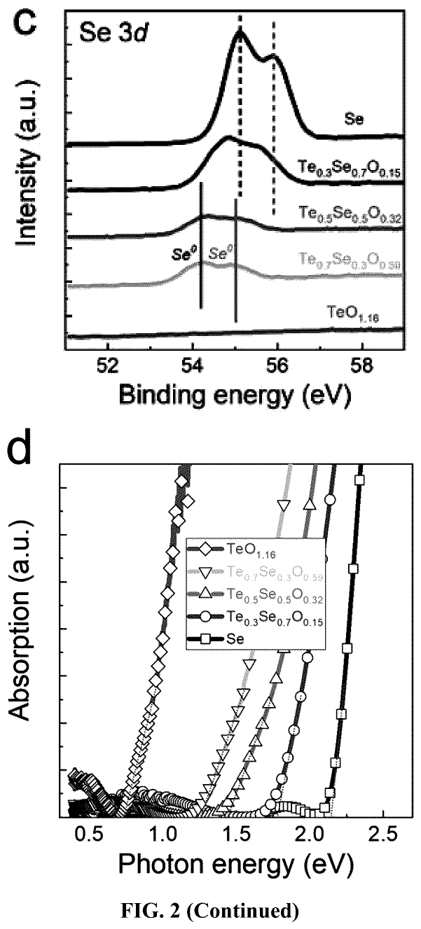

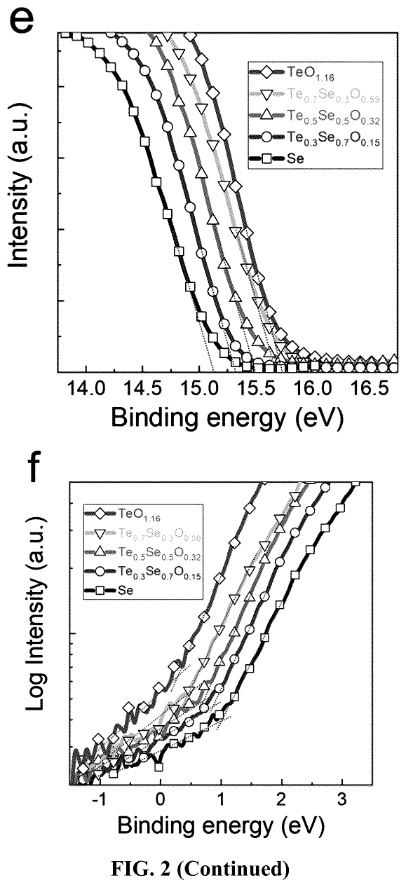

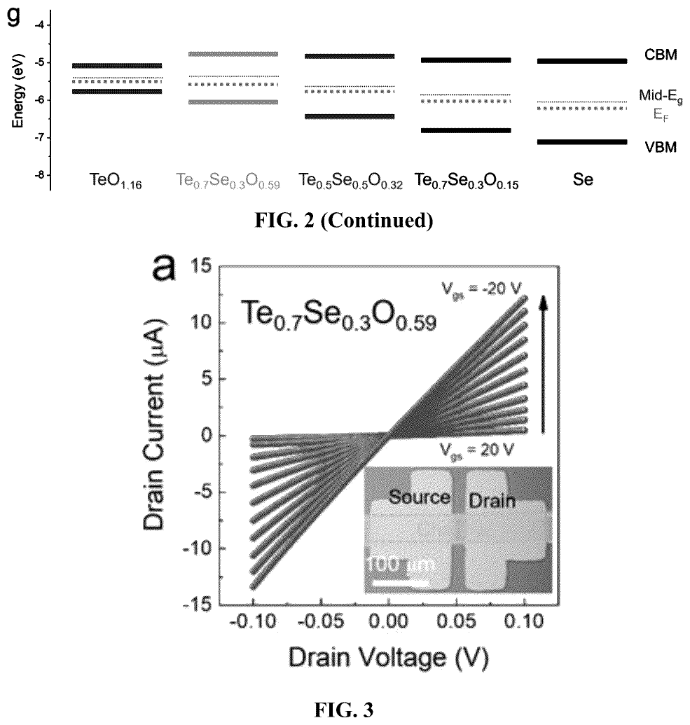

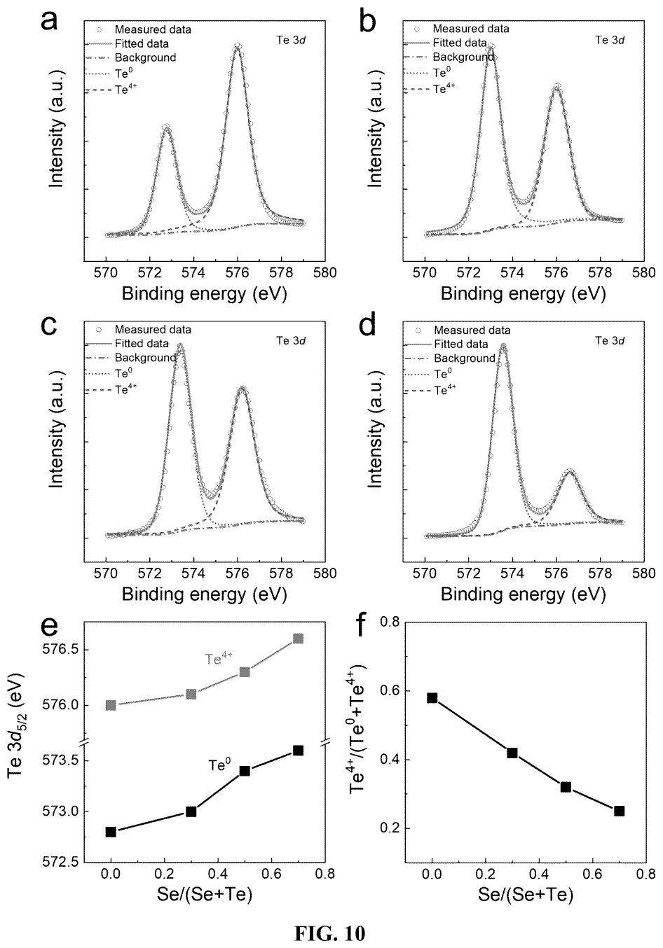

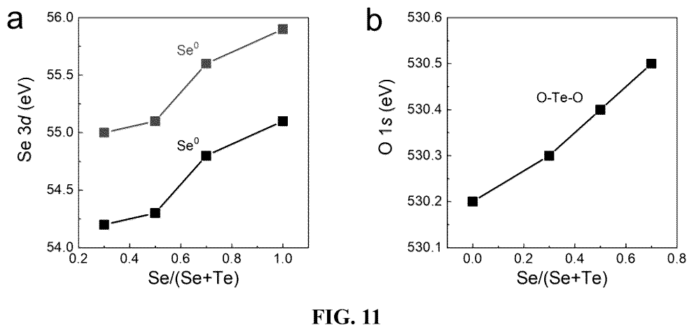

To obtain the details of chemical bonding and atomic coordination in TeSeO thin films, core energy level spectra of Te 3d, O 1s, and Se 3d were studied using XPS (FIGS. 2a to 2c). All three XPS core energy levels of TeSeO exhibit redshifts of up to 800 meV with increasing Se content, resulting from the electron injection process. In detail, the Te⁴⁺ and Te⁰ peaks coexist in the Te 3d spectra of TeSeO thin films (FIG. 2a), which means the partial oxidation of Te. The corresponding Te⁴⁺/(Te⁰⁺+Te⁴⁺) ratios decrease from ˜58% (TeO_{1.16}) to ˜25% (Te_{0.3}Se_{0.7}O_{0.15}) with increasing Se content (FIG. 10 and FIG. 18), revealing that the Se content could suppress the binding process between Te and O. At the same time, no Se⁴⁺. (typically around 60 eV) peak is found from Se 3d spectra in FIG. 2c, mainly owing to its larger electronegativity (2.55) than that of Te (2.1), which make it difficult to react with oxygen molecules to form SeO₂. The distinct peaks observed around 530.2 eV in the O 1s spectra imply the O only acts as lattice oxygen species of O—Te—O (FIG. 2b and FIG. 11). Generally, the adsorbed oxygen or hydroxyl group has higher binding energy around 532 eV, which is not witnessed in our TeSeO films. The gathered information on chemical bonding in inorganic-blended TeSeO, including Te—Te, Te—Se, and O—Te—O, is summarized in Table 1. Overall, the Se-regulating Te oxidation provides a window to change the material compositions among TeO₂ (p-type wide-bandgap semiconductor), TeₓSe_{y} (p-type semiconductor), and Te (p-type semimetal), and thus modify their corresponding physical/chemical properties in a wide range.

TABLE 1
The chemical bonding information of inorganic-blended TeSeO

| Bond | Type | Bandgap | | Character | Function |
|---|---|---|---|---|---|
| Te—Te | Covalent | 0.31 | eV | p-type | High hole |
| | | | | semimetal | mobility |
| Te—Se | Covalent | 0.31~1.87 | eV | p-type | Bandgap |
| | | | | semiconductor | modulation |
| O—Te—O | Polar | 3.7 | eV | p-type wide- | Stability |

| | | |
|---|---|---|
| covalent | bandgap | enhancement |
| | semiconductor | |

In general, continuously tuning bandgaps and band-edge energies in conventional p-type semiconductors is difficult. Apart from the low formation energy of the electron donor, incorporating foreign atoms could inevitably perturb the host lattice thermodynamic equilibrium, possibly counteracting the p-doping effect. These factors restrict the tuning feasibility on hole density and mobility of conventional p-type thin films. This work applies an inorganic blending strategy on the p-type TeSeO system, which combines intrinsic p-type semimetal, semiconductor, and wide-bandgap semiconductor in a single compound. As a result, the p-type TeSeO could be manufactured into scalable thin-film form with reliable and tunable material properties. As presented in FIG. 2d, the optical bandgaps of TeSeO thin films were extracted from the absorption spectra by using the Tauc plot method. With increasing Se content, the energy bandgaps of TeSeO were broadening, with corresponding bandgap values monotonically shifting from 0.7 eV to 2.2 eV. The continuously tunable bandgaps achieved from TeSeO thin films cover ultraviolet (UV), visible, and short-wave infrared (SWIR) regions, revealing potentials in high-mobility p-channel transistors, solar cells, wideband photodetectors, etc.

The quantitatively predictable and available band structures of the TeSeO system are the prerequisite for device-level engineering. To this aim, the electronic structure variations of TeSeO thin films were identified by UPS. The positions of Fermi energy levels and VBM levels could be extracted from the secondary electron cut-off region (FIG. 2e) and valence-band region (FIG. 2f), respectively. Besides, the conduction band minimum (CBM) was calculated by subtracting the bandgap of each sample from its VBM. The corresponding energy band diagrams of TeSeO samples are presented in FIG. 2g. Obviously, for all TeSeO samples, their Fermi energy levels are always underlying the mid-point of bandgaps and relatively close to the valance band, which means that the inorganic-blended TeSeO system keeps p-type electrical properties. It is also found that the energy level of the VBM shifts faster with compositions than that of CBM. Fitting these results to the modified Vegard's law, the energy changes of VBM energies are nearly linear with the composition, while the CBM energies change with a strong bowing of ˜1 eV. This result could be explained by the synergistic effect of Se substitution and partly oxidation in Te.

### Transport Properties and Electrical Robustness of TeSeO

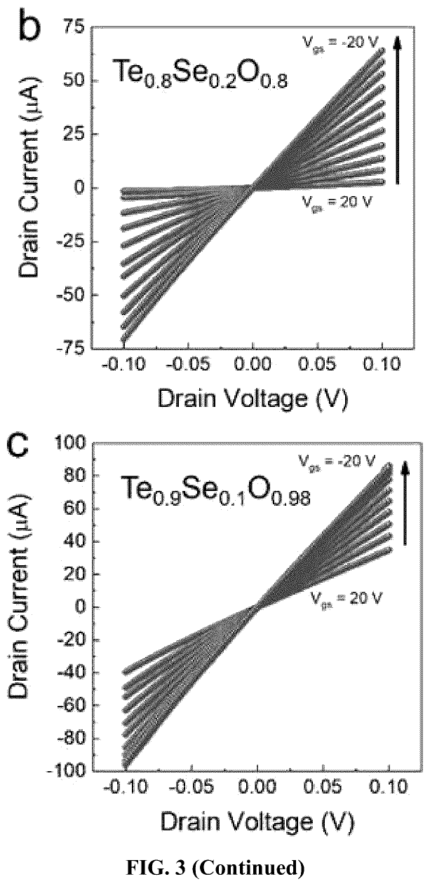

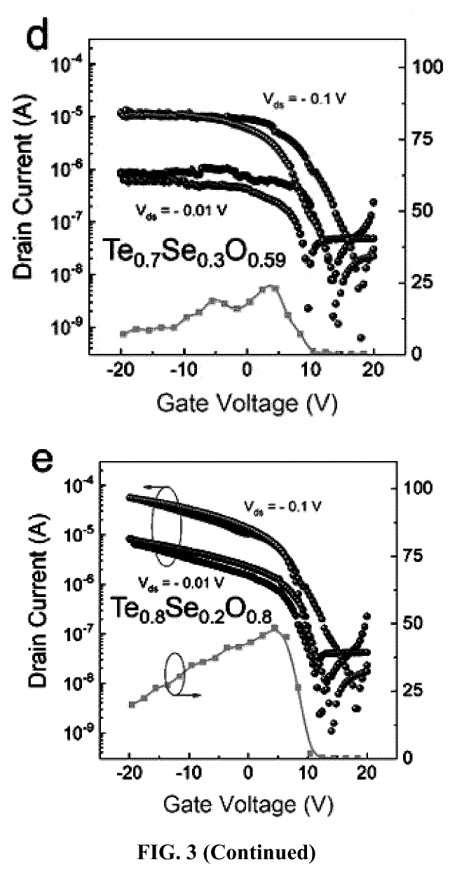

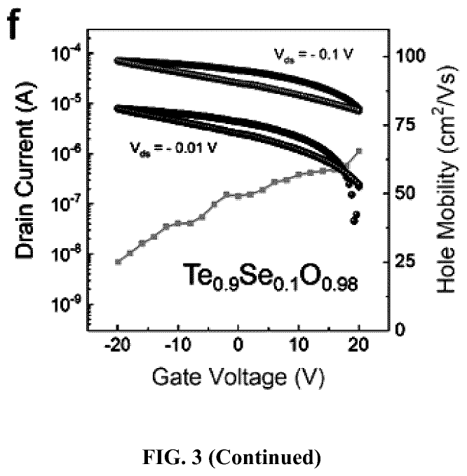

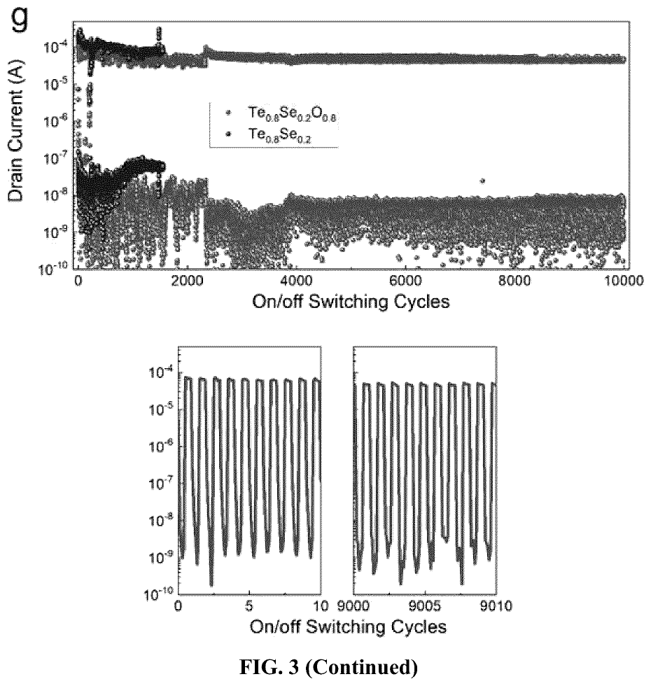

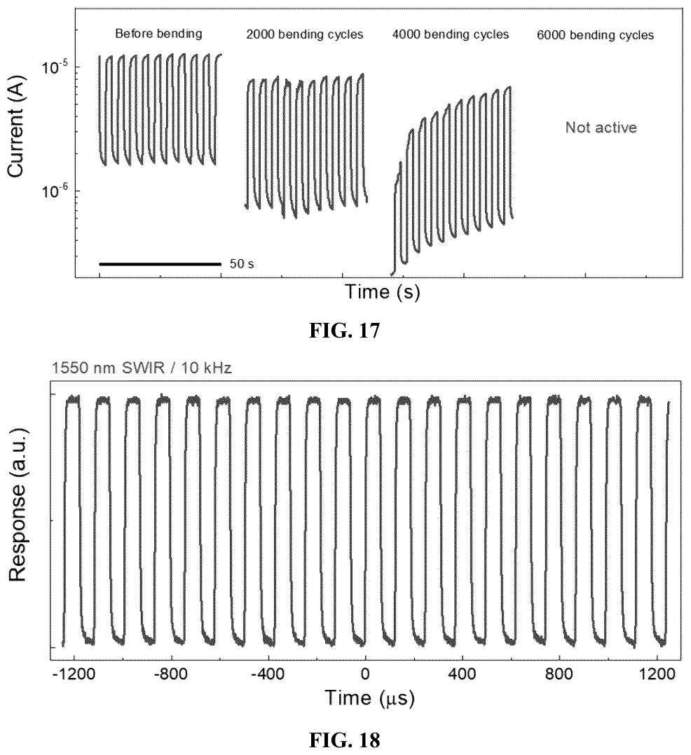

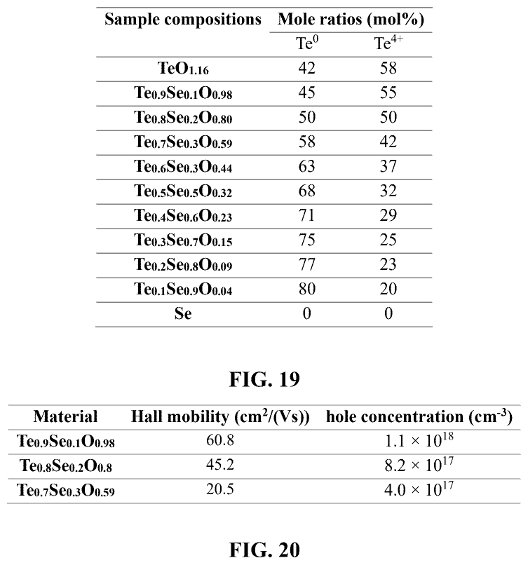

To investigate the hole transport properties of TeSeO thin films, a series of bottom-gate top-contact (BGTC) thin-film transistors (TFTs) are constructed on SiO₂/p⁺-Si wafers with Ni as source/drain electrodes. To guarantee low gate leakage currents and reliable parameter extraction, both channel layers and electrodes are patterned (inset in FIG. 3a). The channel thickness of ˜10 nm, which is verified by cross-sectional STEM, is used to balance the conductivity and the on/off current ratio. As the corresponding electrical characteristics of Te_{0.7}Se_{0.3}O_{0.59}, Te_{0.8}Se_{0.2}O_{0.8}, and Te_{0.9}Se_{0.1}O_{0.98} are shown in FIG. 3, typical p-channel transistor behaviors were observed for those devices, agreeing well with their energy band structures. The Se-poor Te_{0.9}Se_{0.1}O_{0.98} TFT exhibited high conductance and “always-on” transistor operation, which reflected high hole concentration in the channel layer that could not be completely depleted. The Se alloying reduced the current level and mobility in slope and shifted threshold voltage (ITH) in the negative direction (FIGS. 3d to 3f). Meanwhile, the Hall effect measurements of TeSeO films show a similar trend to the electrical properties observed in the TFTs study (FIG. 17).

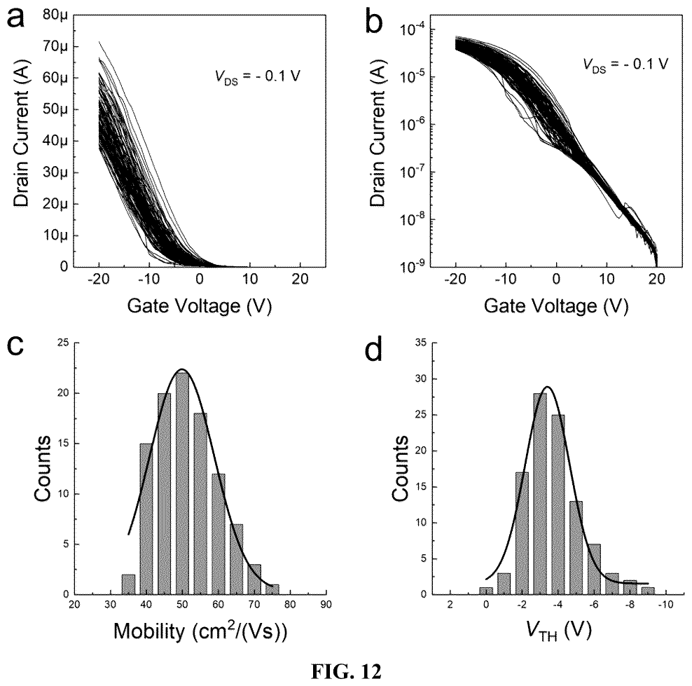

Notably, among all the samples, the Te_{0.8}Se_{0.2}O_{0.8} TFT showed well-optimized electrical performance (FIG. 3e), including a high hole field-effect mobility (μ_{FE}) of 48.5 cm²/(Vs) while maintaining a high Iₒₙ/I_{off} ratio of ˜10⁵. As summarized in FIG. 20, such μ_{FE} and Iₒₙ/I_{off} surpass most previously reported conventional scalable p-channel TFTs, including metal oxides, metal halides, perovskite halides, and organic materials. Besides, the negligible counterclockwise hysteresis indicates the small amounts of electrical traps within TeSeO or at the interface between channel and dielectric layers. To study the scalability and uniformity of TeSeO TFTs, wafer-scale TFT arrays (10×10 array) are fabricated, and their statistical distribution of device performance is displayed in FIG. 12. The TFT array shows 100% device yield with a hole mobility of 48.2±8.4 cm²/(Vs), Iₒₙ/I_{off} of 10⁴˜10⁵, and V_{TH} of −4.2±1.3 V. Such highly uniform electrical performance on the wafer scale is of high significance in the scalable applications of p-type thin-film semiconductors.

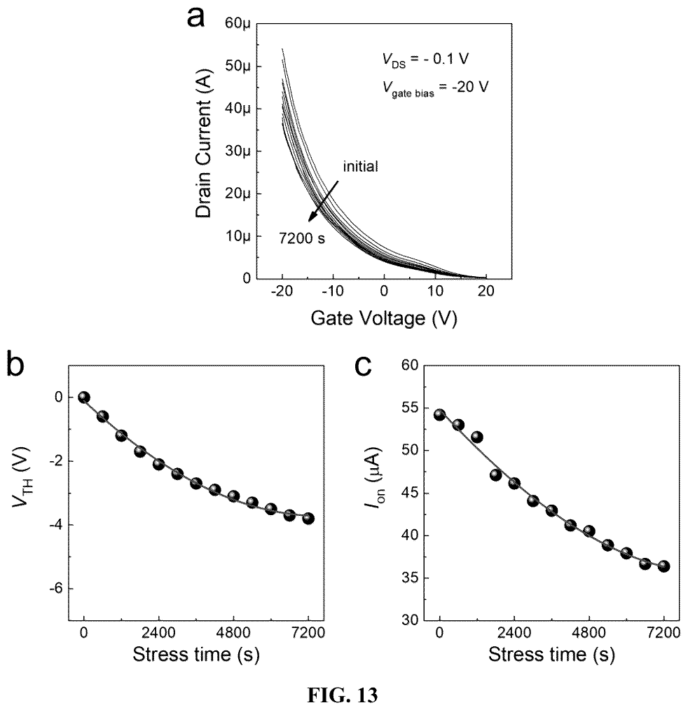

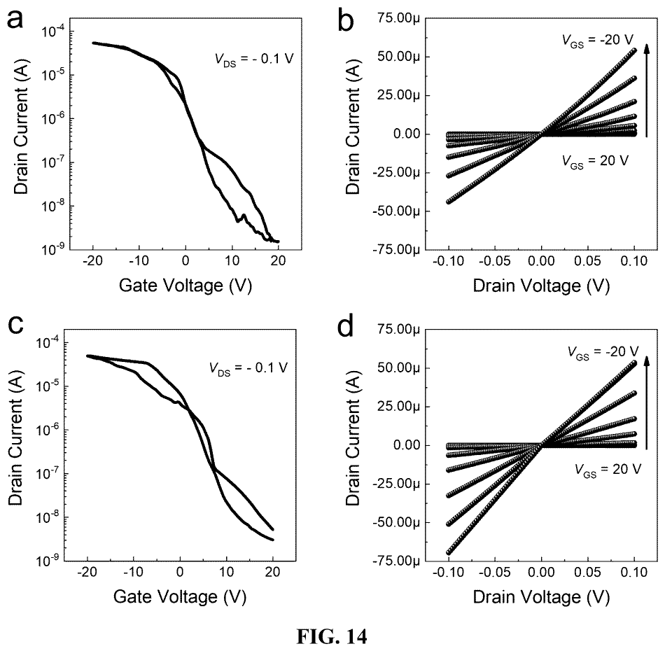

After successfully investigating the intrinsic transport properties of TeSeO thin films, the operational stability in ambient was also checked. As shown in FIG. 3g, with 10,000 times on/off switching, the Te_{0.8}Se_{0.2}O_{0.8} device maintains its output current and good current modulation ability. Meanwhile, a control experiment was also carried out on Te_{0.8}Se_{0.2} samples without oxygen implantation. After 1500 times on/off switching, the Te_{0.8}Se_{0.2} device loses its transistor performance, possibly because of the electrical/thermal induced phase segregation. Negative-bias stress (NBS) testing was also investigated on TeSeO thin films (FIG. 13). After being gated at −20 V for 2 hours, the corresponding V_{TH} shifted negatively from −5 to −8.8 V without noticeable subthreshold swing variation under NBS. Using the equation of σ_{N}=CᵢΔV_{GS}/2e, the charge-trapping states density (σ_{N}) was calculated to be ˜8.2×10¹¹ cm⁻², indicating the defect-state creation is negligible within the NBS test. In addition, benefiting from the partial oxidation in TeSeO thin films that could block the environmental influences, the devices exhibited stable operational stability under the long-term storage test (FIG. 14). After 300 days of ambient storing, the TeSeO TFT performances show no discernible degradation in output current, μ_{FE}, or hysteresis, even without device encapsulation. To the best of our knowledge, the superior operating/environmental durability of TeSeO is unachievable by other p-type thin-film counterparts.

### Broadband Photodetection and Mechanical Robustness of Nanopatterned TeSeO

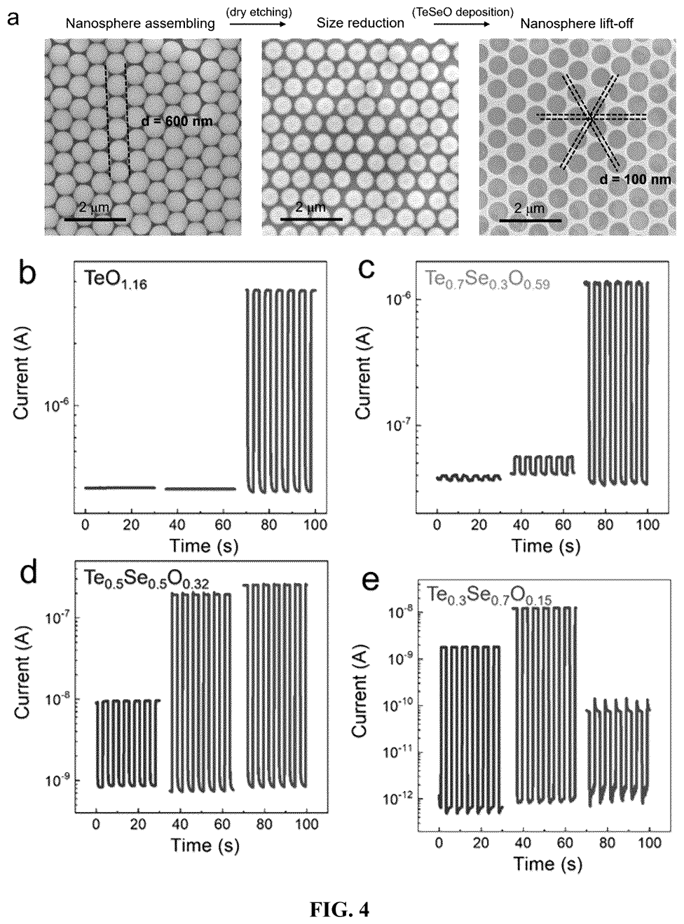

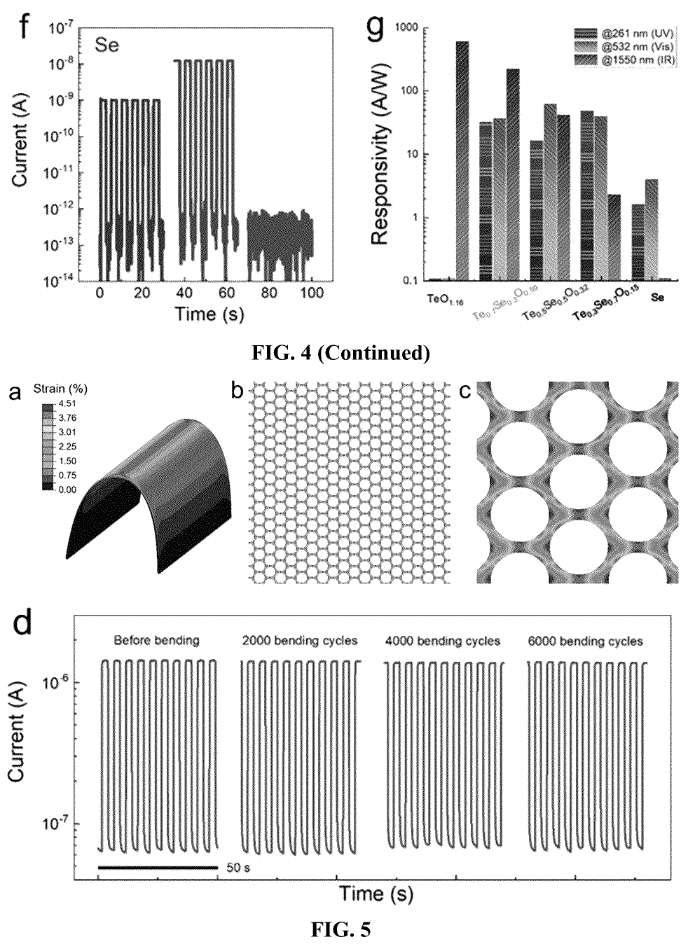

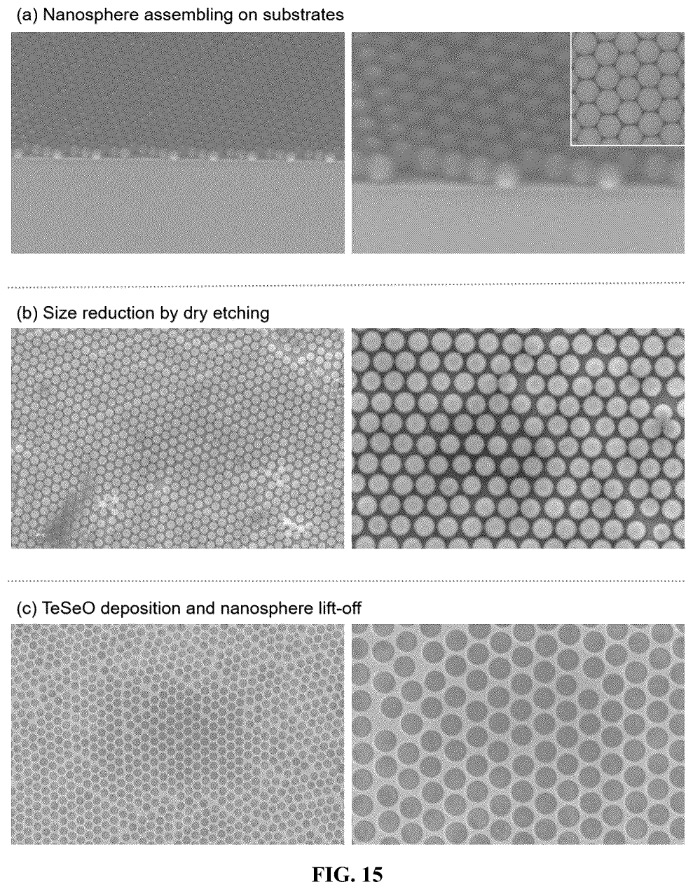

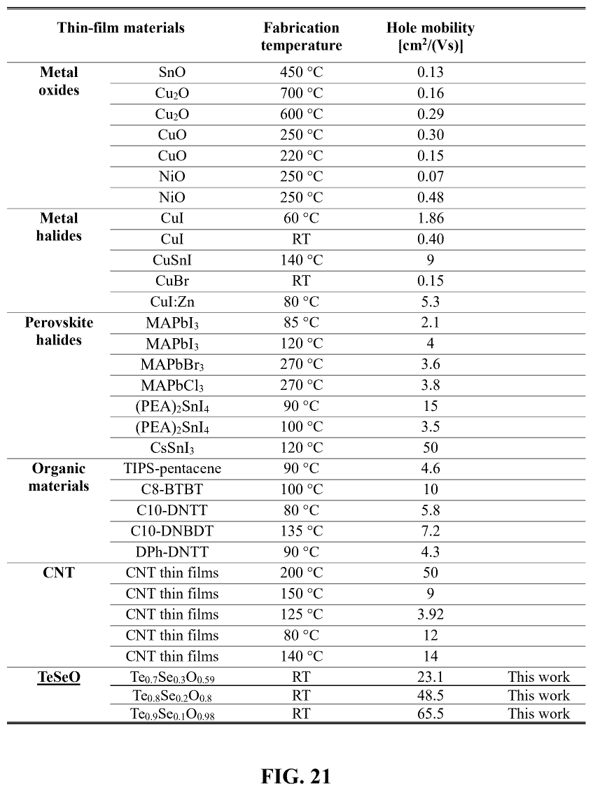

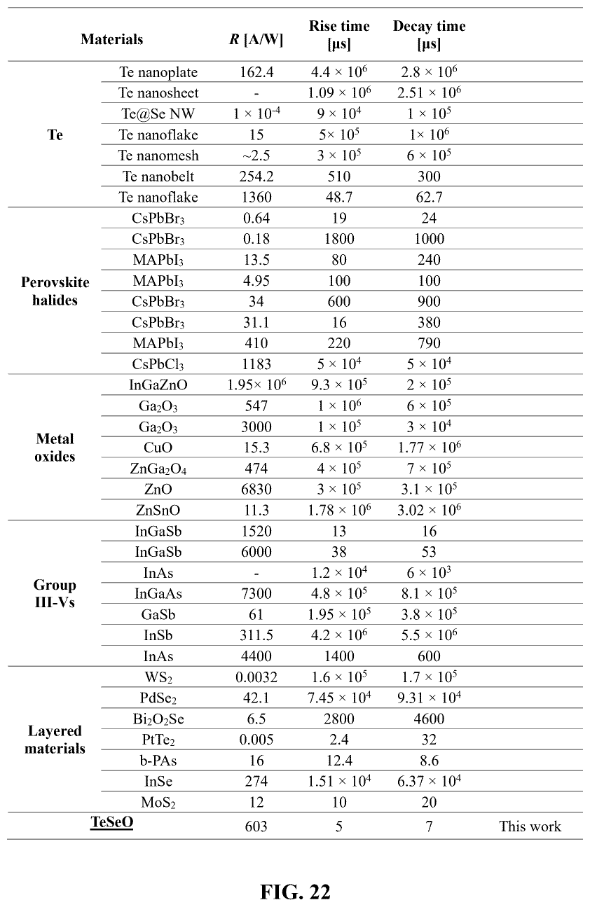

Semiconducting nanostructures are promising for optoelectronics because of their high absorption coefficient and superior flexibility. A maskless nanosphere lithography was employed as a low-cost submicron-scale structure fabrication method to produce honeycomb TeSeO nanostructures on flexible polyimide (PI) substrates (FIG. 4a and FIG. 15, fabrication details shown in Method section). To achieve a good trade-off between flexibility and conductivity, an inter-aperture wire width of ˜100 nm was employed in both experimental study and theoretical modeling. After that, room-temperature photodetecting measurements were carried out using different UV (261 nm), visible (532 nm), and SWIR (1550 nm) light sources. The Te_{0.7}Se_{0.3}O_{0.59}, Te_{0.5}Se_{0.5}O_{0.32}, and Te_{0.3}Se_{0.7}O_{0.15} samples show good photoresponse to these tested wavelengths and yield significant photocurrent under periodic illumination (FIGS. 4c to 4e). Determined by their optical bandgap and absorption efficiency, weak SWIR response was observed at the Se-rich device (FIG. 4f), while the TeO_{1.16} device is highly photosensitive to the SWIR (FIG. 4b). All the performance parameters of flexible TeSeO photodetectors (PDs) are calculated and summarized in FIG. 4g. Specifically, the responsivities of TeO_{1.16} and Te_{0.7}Se_{0.3}O_{0.59} under SWIR irradiation are 603 and 225 A/W, respectively, better than the reported intrinsic Te PDs and comparable to those state-of-the-art wideband PDs (FIG. 21)

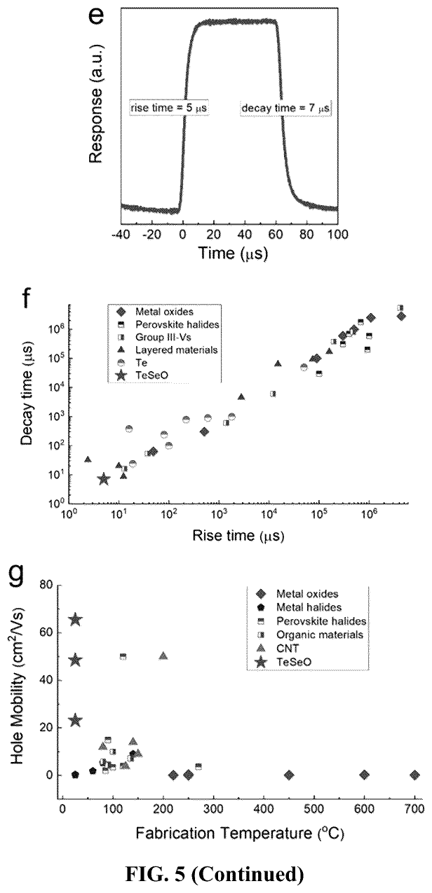

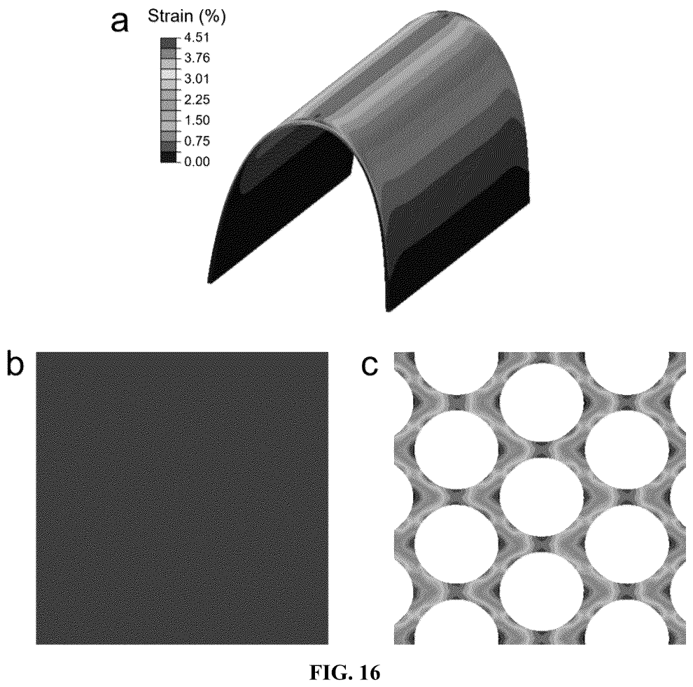

Honeycomb structures with nano/micro-scale geometric dimensions can accommodate mechanical deformations and thereby contribute to the superior flexibility of soft (opto-) electronics. Here, the mechanical response of honeycomb TeSeO nanostructure subject to bending was evaluated by finite element analysis (FEA, see Method section). Impressively, benefiting from the porous structure, the strain on the TeSeO honeycomb channel located on the substrate center is efficiently dispersed with a bending radius of 1.5 mm (FIGS. 5a to 5c and FIG. 16). After that, the simulation conditions were fully reproduced in a real bending experiment to check the mechanical durability of nanopatterned TeSeO PDs directly. The whole bending test with bending times up to 6000 shows no detectable photocurrent deterioration (FIG. 5d). In contrast, the TeSeO flat film without the nanopattern process displayed a significant resistance increase with the bending times (FIG. 17), and eventually, the device broke down because of the appearance of micro-cracks after bending. Thus, it is indicated that the strain-induced structural damage (e.g., plastic deformation and crack initiation) and electrical deterioration in nanopatterned flexible TeSeO could be avoided effectively.

In addition to the high sensitivity and good mechanical flexibility demonstrated above, we benchmark our flexible PD performance with the transient response speed, which highly depends on the efficient collection/transport of photo-generated carriers. The transient output signals of nanopatterned Te_{0.7}Se_{0.3}O_{0.59} PDs were measured under modulated 1550 nm illumination. Even with a chopping frequency high to 10 kHz, the devices exhibit high response reliability without signal distortion (FIG. 18). More importantly, the Te_{0.7}Se_{0.3}O_{0.59} devices exhibit ultra-fast optical response with the rise and decay times being 5 μs and 7 μs (FIG. 5e). The μs-level response time is better than most p-channel PDs reported in the literature (FIG. 5f), mainly due to the intrinsic high hole mobility of inorganic-blended TeSeO and the high surface-to-volume ratio of honeycomb structure (FIG. 5g). These observations promise future air-stable and high-speed optoelectronic applications based on p-type band-tunable semiconductors.

To summarize, TeSeO, a versatile p-type inorganic semiconductor system, was designed and deposited as thin films and honeycomb nanostructures at room temperature. By utilizing an inorganic blending strategy, the band structure of TeSeO was engineered to meet the specific technical requirements. For instance, by optimizing the TeSeO formulation, Te_{0.8}Se_{0.2}O_{0.8} TFTs show high/FE of 48.5 cm²/(Vs) and Iₒₙ/I_{off} of ˜10⁵, while the flexible honeycomb Te_{0.7}Se_{0.3}O_{0.59} broadband PDs show fast optical response down to 5 μs. Importantly, benefiting from the partial oxidation in TeSeO, the devices exhibited good operational robustness under long-term storage and persistent bias. These performance parameters surpass those of conventional p-type thin films (e.g., metal oxides, metal halides, perovskite halides, and organic materials) and are on par with the state-of-art n-type scalable metal oxides (e.g., a-InGaZnO). In this regard, the inorganic-blended TeSeO system could be applied to diverse functional utilization beyond the immediate interests in (opto-) electronics.

### EXAMPLES

Material synthesis. The whole fabrication process of TeSeO films was conducted at room temperature in a scalable manner. First, the SiO₂ and polyimide (PI) substrates used in this work were ultrasonically cleaned in acetone, ethanol, and deionized water and dried by nitrogen gas. Before using, Te (Sigma-Aldrich, 99.997%, powder) and Se (Sigma-Aldrich, 99.99%, powder) were mixed and then ground for 30 minutes. Due to the higher vapor pressure of Se than Te, less Se powder compared with the desired Te/Se ratio was added to the mixed source powder. For instance, to achieve the Te/Se ratios of 7/3, 5/5, and 3/7, the Se powder with percentages of 17%, 38%, and 55% was added to the mixed source, respectively. After that, a thermal evaporation process with a deposition rate of 2 Å/second was utilized to deposit TeSe thin films with a chamber pressure below 4×10⁻⁶ Torr at room temperature. The film thickness is proportional to the deposition time, monitored by an INFICON SQC-310 deposition controller combined with a quartz crystal oscillator. To achieve oxygen implantation in TeSeO thin films, a standard oxygen implantation technique (PC-150, JunSun Tech Co., Ltd.) was employed with a plasma power of 30 W and an O₂ gas flow of 50 sccm. The chamber pressure was set to 0.26 Torr during the oxygen implantation process with a duration of 60 seconds.

Material characterization. Surface morphologies of TeSeO films were examined with scanning electron microscopy (SEM, FEI Quanta 450 FEG SEM) and atomic force microscopy (AFM, Bruker Dimension Icon AFM). A Rigaku SmartLab X-ray Diffractometer (XRD) with Cu Kα radiation was used to evaluate the crystallinity and crystal structure of the TeSeO films. To get a stronger signal from the TeSeO film and avoid signal from the substrate, grazing-incidence XRD measurement was performed with a fixed grazing incidence angle of 1°. Crystal structures were also determined by high-resolution transmission electron microscopy (HRTEM, JEOL 2100F). Elemental mappings were performed using an energy-dispersive X-ray spectroscopy (EDS) detector attached to a spherical-aberration-corrected scanning transmission electron microscopy (STEM, JEOL JEM-ARM300F2). To realize the elemental and chemical analysis of samples, a Thermo Scientific ESCALAB 250Xi system was employed to perform UPS and XPS. Before UPS and XPS measurement, the samples were cleaned by Ar⁺ ion etching to remove surface contamination. All the XPS peaks were calibrated by carbon (C 1s) peaked at 284.8 eV.

Nanosphere lithography. The monodispersed suspension of polystyrene (PS) nanospheres (10 wt %, in water, diameter of 600 nm) was used in this work. First, PS nanospheres were self-assembled into close-packed hexagonal arrays at the water-air interface. Then, the close-packed monolayers of PS nanospheres were transferred onto a flexible PI substrate, serving as lithographic masks. After that, a time-dependent dry oxygen etching process was used to tailor the diameter of PS nanospheres to ˜500 nm, which was performed under O₂ (50 sccm) at a pressure of 0.26 Torr and a radio frequency power of 30 W for 45 seconds. After TeSeO film deposition, the nanospheres were lifted off by ultrasonicating the samples in toluene for 60 seconds, and the TeSeO honeycomb layer with an inter-aperture wire width of ˜100 nm was formed on the PI substrates.

Finite element analysis (FEA). The mechanical performance of honeycomb TeSeO nanostructures on flexible PI substrates under bending behavior was simulated and analyzed using FEA with the commercial software ABAQUS. The model used in this simulation was developed based on real bending experiments and incorporated the actual geometries and loading history. The PI substrate bent into a semi-circle with a radius of 1.5 mm, causing the attached honeycomb TeSeO nanostructures to deform accordingly. The slip between the substrate and the TeSeO film in the model is neglected. The linear elastic constitutive model was considered in the FEA simulation, where TeSeO has a Young's modulus of 31.1 GPa, and PI has a Young's modulus of 2.5 GPa, while their Poisson's ratios are 0.33 and 0.39, respectively. The maximum principle strain distribution of the TeSeO film was obtained in this model.

Device fabrication and characterization. Bottom-gate top-contact thin-film transistors were constructed on p⁺-Si/SiO₂ substrates, in which the thermally grown oxide thickness is 50 nm. Both channel layers and source/drain electrodes are patterned through shadow masking to guarantee low gate leakage currents and reliable parameter extraction. The TeSeO channel thickness is ˜10 nm in this work. The 70-nm thick Ni source/drain electrodes were deposited by electron beam evaporation, with a channel width/length of 100 μm/40 μm. Ni electrodes have a high work function of ˜5.1 eV, suitable for contact with p-type semiconductors. Agilent 4155C semiconductor analyzer was employed to realize electrical characterizations with help from a standard electrical probe station. Field-effect mobility (μ_{FE}) in the linear regime can be calculated using μ_{FE}=Lgₘ/(WCᵢV_{DS}), where L, W, Cᵢ, and V_{DS} are the channel length, channel width, gate capacitance per unit area, drain-source voltage, respectively. The gₘ was transconductance defined as ∂I_{DS}/∂V_{GS}, where I_{DS} is drain-source current and V_{GS} is gate-source voltage. The Cᵢ was calculated from the parallel plate capacitor model, using Cᵢ=(εA)/d, where the dielectric constant (ε) and film thickness (d) of the SiO₂ dielectric layer are 3.9 and 50 nm, respectively. The Ecopia HMS 5300 Hall effect measurement system, equipped with a 0.54 T permanent magnet, was employed to measure the carrier concentration and Hall mobility using the van der Pauw method. For the photodetector measurements, lasers with different wavelengths of ultraviolet (261 nm), visible (532 nm), and short-wave infrared (1550 nm) were used as the light sources, in which their incident light powers (P) were determined by a power meter (PM400, Thorlabs). To quantify the photodetecting performance, responsivity (R) was estimated using R=Iₚ/(PA), where Iₚ is photocurrent (defined as light current minus dark current) and A is the effective irradiated area. The rise and decay times of photodetectors are determined as the time to vary from 10% to 90% of the peak photocurrent and vice versa.

What is claimed is:

1. A semiconductor composition comprising tellurium, selenium, and oxygen, wherein the semiconductor composition is substantially free of Se⁴⁺.

2. The semiconductor composition of claim 1, wherein the semiconductor composition comprises Te⁰, Se⁰, and Te⁴⁺, wherein regions comprising Te⁰ and Se⁰ are substantially crystalline or polycrystalline and regions comprising Te⁴⁺ are substantially amorphous.

3. The semiconductor composition of claim 1, wherein the semiconductor composition has a hole mobility between 23.1-65.6 cm²/(Vs) at room temperature.

4. The semiconductor composition of claim 1, wherein the semiconductor composition has a bandgap of 0.7 eV to 2.2 eV.

5. The semiconductor composition of claim 1, wherein the semiconductor composition is Te₍₁₋ₓ₎SeₓO_{y}, wherein 0.1≤x≤0.9 and 0.04≤y≤0.98.

6. The semiconductor composition of claim 1, wherein the semiconductor composition is Te₍₁₋ₓ₎SeₓO_{y}, wherein 0.1≤x≤0.3 and 0.59≤y≤0.98.

7. The semiconductor composition of claim 1, wherein the semiconductor composition is Te₍₁₋ₓ₎SeₓO_{y}, wherein 0.1≤x≤0.3 and y±0.01=1.18-1.95x.

8. The semiconductor composition of claim 1, wherein the semiconductor composition is Te₍₁₋ₓ₎SeₓO_{y}, wherein 0.1≤x≤0.9 and 0.04≤y≤0.98; and the semiconductor composition has a bandgap of 0.7 eV to 2.2 eV.

9. The semiconductor composition of claim 8, wherein the semiconductor composition has a hole mobility between 23.1-65.6 cm²/(Vs).

10. The semiconductor composition of claim 1, wherein the semiconductor composition is Te₍₁₋ₓ₎SeₓO_{y}, wherein 0.1≤x≤0.3 and 0.59≤y≤0.98; and the semiconductor composition has a bandgap of 0.7 eV to 2.2 eV.

11. The semiconductor composition of claim 10, wherein the semiconductor composition has a hole mobility between 23.1-65.6 cm²/(Vs).

12. The semiconductor composition of claim 1, wherein the semiconductor composition is selected from the group consisting of Te_{0.7}Se_{0.3}O_{0.59}, Te_{0.8}Se_{0.2}O_{0.80}, and Te_{0.9}Se_{0.1}O_{0.98}.

13. A method for preparing the semiconductor composition of claim 1, the method comprising:
combining tellurium (Te) powder and selenium (Se) powder thereby forming a Te—Se mixture;
depositing the Te—Se mixture on a surface of a substrate by physical vapor deposition thereby forming a Te—Se film; and
contacting the Te—Se film with oxygen plasma thereby forming the semiconductor composition.

14. The method of claim 13, wherein the Te powder and the Se powder are combined in a molar ratio of 1:9 to 9:1, respectively.

15. The method of claim 13, wherein the Te powder and the Se powder are combined in a molar ratio of 7:3 to 9:1, respectively.

16. The method of claim 13, wherein the oxygen plasma is generated at a power of 30-100 W under a pressure of 0.1-10 Torr.

17. A semiconductor device comprising the semiconductor composition of claim 1, wherein the semiconductor device is selected from the group consisting of a thin-film transistor, a photodetector, and a solar cell.

18. The semiconductor device of claim 17, wherein the semiconductor device is a thin-film transistor having a hole mobility between 23.1-65.6 cm²/(Vs) or a photodetector having a response speed of about 5 μs.
